(19) United States
(12) Patent Application Publication
(10) Pub. No.: US 2026/0136619 A1
(43) Pub. Date: May 14, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Toshiki MII, Nisshin-shi (JP); Ryota SUZUKI, Nisshin-shi (JP)

(21) Appl. No.: 19/309,734

(22) Filed: Aug. 26, 2025

(30) Foreign Application Priority Data
Nov. 8, 2024 (JP) 2024-196076

(51) Int. Cl. H10D 62/60; H01L 23/528; H10D 30/66; H10D 62/10; H10D 62/832

(52) U.S. Cl. CPC H10D 62/60; H10D 30/668; H10D 62/111; H10W 20/427; H10D 62/8325

(57) ABSTRACT

A depletion region of a first conductivity type is arranged in an upper surface layer of a body layer, and located below a gate wiring. The depletion region is depleted when a voltage applied between a lower electrode and an upper electrode is 0 V. The depletion region is positioned under an end portion of the gate wiring, and an upper surface of the body layer is exposed from the depletion region at location inward of the end portion of the gate wiring.

### CROSS REFERENCE TO RELATED APPLICATION

This application is based on Japanese Patent Application No. 2024-196076 filed on Nov. 8, 2024, the disclosure of which is incorporated herein by reference.

### TECHNICAL FIELD

The present disclosure relates to a semiconductor device.

### BACKGROUND

A semiconductor device includes a Metal Oxide Semiconductor Field Effect Transistor (MOSFET) element, in which a body layer is disposed on an upper surface of a drift layer. A drain electrode is formed on a lower surface of the drift layer, and a gate wiring and a source electrode are formed on an upper surface of the body layer.

### SUMMARY

According to one aspect of the present disclosure, a semiconductor device includes: a drift layer of a first conductivity type; a body layer of a second conductivity type on an upper surface of the drift layer; a lower electrode on a lower surface of the drift layer; a gate wiring disposed on an upper surface of the body layer and connected to a gate electrode; a gate insulating film formed between the upper surface of the body layer and the gate wiring; and an upper electrode on the upper surface of the body layer. A depletion region of the first conductivity type is formed in an upper surface layer of the body layer, and depleted when an applied voltage between the lower electrode and the upper electrode is 0 V. The depletion region is located below at least part of an end portion of the gate wiring. The upper surface of the body layer may be exposed from the depletion region, at location inward of the end portion of the gate wiring.

### BRIEF DESCRIPTION OF DRAWINGS

FIG. 1 is a cross-sectional view of a semiconductor device according to a first embodiment.

FIG. 2 is an enlarged view of a depletion region in FIG. 1.

FIG. 3 is a top view of a body layer.

FIG. 4A is a cross-sectional view showing a manufacturing step of the semiconductor device.

FIG. 4B is a cross-sectional view showing a subsequent manufacturing step of the semiconductor device following FIG. 4A.

FIG. 4C is a cross-sectional view showing a subsequent manufacturing step of the semiconductor device following FIG. 4B.

FIG. 4D is a cross-sectional view showing a subsequent manufacturing step of the semiconductor device following FIG. 4C.

FIG. 5 is a cross-sectional view of a comparative example.

FIG. 6 is a cross-sectional view showing a path resistance in the first embodiment.

FIG. 7 is a cross-sectional view of a semiconductor device according to a second embodiment.

FIG. 8 is a cross-sectional view of a semiconductor device according to a third embodiment.

FIG. 9 is a top view of a body layer in a fourth embodiment.

FIG. 10 is a top view of a body layer in a modification of the fourth embodiment.

FIG. 11 is a top view of a body layer in another embodiment.

FIG. 12 is a top view of a body layer in another embodiment.

### DETAILED DESCRIPTION

A semiconductor device includes a Metal Oxide Semiconductor Field Effect Transistor (MOSFET) element, in which a body layer is disposed on an upper surface of a drift layer. A drain electrode is formed on a lower surface of the drift layer, and a gate wiring and a source electrode are formed on an upper surface of the body layer.

In such a semiconductor device, during recovery operation, a displacement current flows into the body layer via a PN junction capacitance between the drift layer and the body layer. At this time, the potential of the body layer increases due to the path resistance of the body layer, resulting in a potential difference between the gate wiring and the body layer. If this potential difference increases, a high electric field is applied to the gate insulating film between the body layer and the gate wiring, making it more susceptible to breakdown.

In a MOSFET element, a p-type body layer is stacked on the upper surface of an n-type drift layer, and a p+ type region is formed in the upper surface layer of the body layer to be in contact with the gate insulating film.

The p+ type region is formed across the entire region of the surface layer of the body layer located beneath the gate wiring. The p+ type region is covered on its side and bottom surfaces by an n+ type region connected to the source potential. The p-type region of the body layer and the p+ type region are separated by the n+ type region. With such a configuration, it is possible to suppress the displacement current from entering the p+ type region and to restrict breakdown of the gate insulating film due to a potential increase in the p+ type region.

In the semiconductor device, the p-type region becomes thinner beneath the p+ type region and the n+ type region, compared to other portions, resulting in the path resistance for displacement current in the p-type region being greater than in other areas. Therefore, if the p+ type region and the n+ type region are formed across the entire surface layer of the body layer beneath the gate wiring, the area with high path resistance becomes extensive, which may cause localized temperature increase during recovery operation and potentially lead to device failure.

The present disclosure provides a semiconductor device capable of improving recovery breakdown tolerance.

According to one aspect of the present disclosure, a semiconductor device includes: a drift layer of a first conductivity type; a body layer of a second conductivity type on an upper surface of the drift layer; a lower electrode on a lower surface of the drift layer; a gate wiring formed on an upper surface of the body layer and connected to a gate electrode; a gate insulating film formed between the upper surface of the body layer and the gate wiring; and an upper electrode on the upper surface of the body layer. A depletion region of the first conductivity type is formed in an upper surface layer of the body layer, and depleted when the applied voltage between the lower electrode and the upper electrode is 0 V. The depletion region is formed below the gate wiring. The depletion region is positioned under at least part of an end portion of the gate wiring, and the upper surface of the body layer is exposed from the depletion region, at location inward of the end portion of the gate wiring.

The depletion region is less susceptible to the effects of potential rise caused by the flow of displacement current in the body layer. Therefore, forming a depletion region beneath the gate wiring reduces the electric field applied to the gate insulating film. In the vicinity of the end portion of the gate wiring, a higher electric field tends to be applied to the gate insulating film, compared to the region inward of the end portion, making breakdown more likely to occur. Therefore, by forming a depletion region under at least part of the end portion of the gate wiring, it is possible to suppress breakdown of the gate insulating film. Furthermore, since the upper surface of the body layer is exposed from the depletion region at least beneath the region inward of the end portion of the gate wiring, it is possible to suppress an increase in path resistance at the location, thereby restricting device breakdown due to temperature rise. As a result of these measures, the recovery breakdown tolerance can be improved.

Hereinafter, embodiments of the present disclosure will be described with reference to the drawings. In the following description of the respective embodiments, parts that are identical or equivalent to each other will be denoted by the same reference numerals.

### First Embodiment

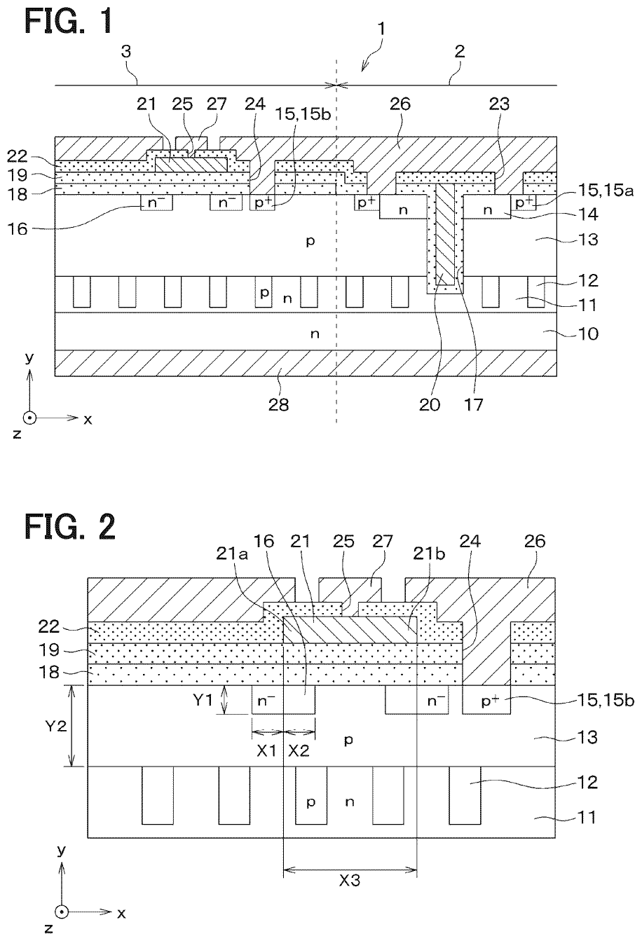

A first embodiment will be described below. As shown in FIG. 1, a semiconductor device 1 includes a MOSFET element. The semiconductor device 1 operates as a MOSFET element in an active region 2, while the other region is referred to as an inactive region 3. In the present embodiment, the MOSFET element included in the semiconductor device 1 is an n-channel element, in which the n-type is a first conductivity type and the p-type is a second conductivity type.

The semiconductor device 1 includes a substrate 10. The substrate 10 is made of n-type SiC (silicon carbide). An n-type drift layer 11 is formed on the upper surface of the substrate 10.

A surface direction parallel to the upper surface of the body layer 13 is defined as x-direction. A direction perpendicular to the upper surface of the body layer 13, that is, the thickness direction of the body layer 13, is defined as y-direction. A direction parallel to the upper surface of the body layer 13 and perpendicular to the x-direction is defined as z-direction.

The drift layer 11 is configured to function as an electric field relaxation layer. Specifically, plural linear p-type column regions 12, which extend in the z-direction, are formed in the surface layer of the drift layer 11 on the upper side. The surface layer of the drift layer 11 has an SJ (Super Junction) structure in which n-type regions and the p-type column regions 12 are alternately arranged in the x-direction.

A body layer 13 doped with p-type impurities is stacked on the upper surface of the drift layer 11. An n-type region 14, a p+ type region 15, and a depletion region 16 are formed in the surface layer of the body layer 13 on the upper side.

The n-type region 14 is formed in the active region 2, and the depletion region 16 is formed in the inactive region 3. A part of the p+ type region 15 is formed in the active region 2, and the other part is formed in the inactive region 3. The part of the p+ type region 15 formed in the active region 2 is referred to as the p+ type region 15a, and the other part formed in the inactive region 3 is referred to as the p+ type region 15b.

A trench 17 is formed in the active region 2 to penetrate through the body layer 13 and the n-type region 14, into the drift layer 11. The n-type region 14 is disposed on both sides of the trench 17 in the x-direction.

The p+ type region 15 has a higher p-type impurity concentration than the p-type column region 12 and the body layer 13. The p+ type region 15a is formed in contact with the n-type region 14, opposite to the trench 17. That is, the p+ type region 15a has a first portion in contact with the n-type region 14 located on one side in the x-direction of the trench 17, and a second portion in contact with the n-type region 14 located on the other side in the x-direction of the trench 17.

The p+ type region 15b is a contact portion that connects the body layer 13 to a source electrode 26, and is disposed between the active region 2 and the depletion region 16. The depletion region 16 is disposed below the end portion of a first gate wiring 21, which will be described later. The depletion region 16 has an n-type impurity concentration lower than that of the substrate 10, the drift layer 11, and the n-type region 14. The depletion region 16 is depleted when the voltage applied between the drain electrode 28 and the source electrode 26 is 0 V.

A field insulating film 18 made of SiO₂ (silicon oxide) is arranged on the upper surface of the body layer 13 included in the inactive region 3. The upper surface of the depletion region 16 is covered with the field insulating film 18. A gate insulating film 19 made of SiO₂ is arranged on the upper surface of the field insulating film 18 and on the upper surface of the body layer 13 exposed from the field insulating film 18. The gate insulating film 19 is formed inside the trench 17, and the wall surface and bottom surface of the trench 17 are covered with the gate insulating film 19.

A polycrystalline silicon (Poly-Si) is filled inside the trench 17, to form the gate electrode 20. The gate electrode 20 is insulated from the drift layer 11, the body layer 13, and the n-type region 14 by the gate insulating film 19. The first gate wiring 21 made of polycrystalline silicon (Poly-Si) is formed on the upper surface of the gate insulating film 19. The first gate wiring 21 is a lead wire for connecting the gate electrode 20 to a second gate wiring 27, and is connected to the gate electrode 20 at a portion not shown in FIG. 1. An interlayer insulating film 22 made of SiO₂ is formed on the upper surface of the gate insulating film 19, the gate electrode 20, and the first gate wiring 21.

A trench 23 is formed in the active region 2 to penetrate through the gate insulating film 19 and the interlayer insulating film 22, to expose the upper surface of the n-type region 14 and the p+ type region 15a.

A trench 24 is formed in the inactive region 3 to penetrate through the field insulating film 18, the gate insulating film 19, and the interlayer insulating film 22, to expose the upper surface of the p+ type region 15b. A trench 25 is formed in the inactive region 3 to penetrate through the interlayer insulating film 22, to expose the upper surface of the first gate wiring 21.

An Al—Si (aluminum-silicon) layer is arranged on the upper surface of the interlayer insulating film 22, to form the source electrode 26 and the second gate wiring 27. The source electrode 26 corresponds to the upper electrode. A recess is formed between the source electrode 26 and the second gate wiring 27 to expose the upper surface of the interlayer insulating film 22. The source electrode 26 and the second gate wiring 27 are electrically insulated from each other. The source electrode 26 is formed not only on the upper surface of the interlayer insulating film 22, but also inside the trench 23, 24, and is connected to the n-type region 14, the p+ type region 15a and the p+ type region 15b.

The second gate wiring 27 is formed not only on the upper surface of the interlayer insulating film 22, but also inside the trench 25, and is connected to the first gate wiring 21. The gate electrode 20 is connected to a pad (not shown) via the first gate wiring 21 and the second gate wiring 27. The drain electrode 28 made of Al—Si is arranged on the lower surface of the substrate 10. The drain electrode 28 corresponds to the lower electrode.

The details of the arrangement of the depletion region 16 will be described. The depletion region 16 is formed at least partially beneath an end portion of the first gate wiring 21. The depletion region 16 is not formed at least partially beneath the first gate wiring 21 located inward of the end portion, and the upper surface of the body layer 13 is exposed from the depletion region 16 at least partially beneath the first gate wiring 21 located inward of the end portion.

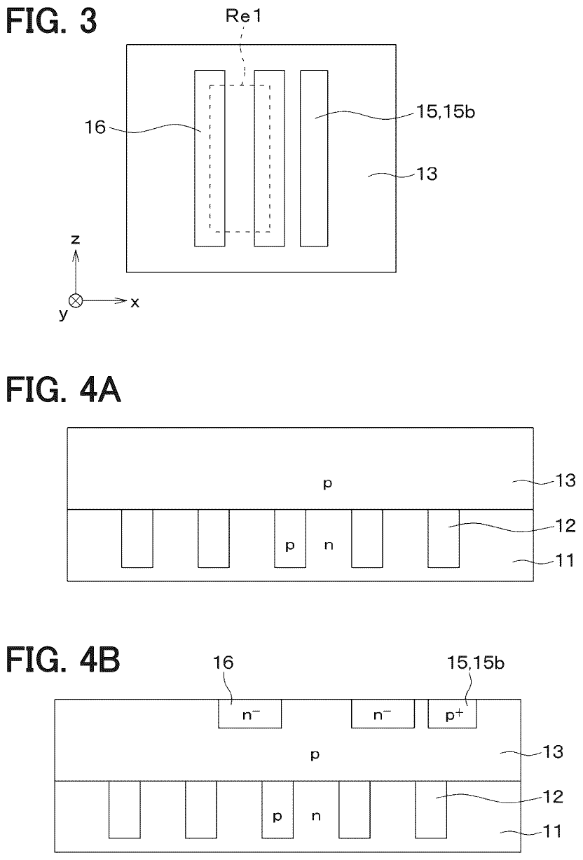

In the present embodiment, the depletion region 16 is formed at the positions shown in FIGS. 2 and 3. A region Re1 in FIG. 3 indicates a part of the body layer 13 that faces the first gate wiring 21. FIG. 2 illustrates only a part of the first gate wiring 21. FIG. 3 illustrates the region Re1 of the body layer 13 that faces the part of the first gate wiring 21 shown in FIG. 2.

Specifically, the first gate wiring 21 includes a rectangular portion having the z-direction as its longitudinal direction and the x-direction as its lateral direction, as well as a connection portion that connects the rectangular portion to the gate electrode 20. FIG. 2 illustrates only the rectangular portion of the first gate wiring 21, while FIG. 3 illustrates the region Re1 facing the rectangular portion.

The first gate wiring 21 has a first end portion 21a and a second end portion 21b in the x-direction. The first end portion 21a is located opposite to the p+ type region 15b with respect to the center of the first gate wiring 21. The second end portion 21b is located adjacent to the p+ type region 15b with respect to the center of the first gate wiring 21. As shown in FIG. 3, the depletion region 16 is formed as a linear region extending in the z-direction along the first end portion 21a and the second end portion 21b.

The dimensions of the depletion region 16 will be described. As shown in FIG. 2, the depletion region 16 protrudes outward from the end portion of the first gate wiring 21 in the x-direction, and the dimension of the protrusion in the x-direction is defined as X1. A part of the depletion region 16 overlaps with the first gate wiring 21 in the x-direction. The dimension of the overlap in the x-direction is defined as X2. The dimension of the first gate wiring 21 in the x-direction is defined as X3.

As will be described later, the depletion region 16 suppresses the breakdown of the field insulating film 18 and the gate insulating film 19. To achieve this effect, it is desirable that 0<X1<5 μm and 0<X2<X3 are satisfied. The conditions for X1 and X2 are not mandatory. For example, X1 may be zero. Alternatively, X1 may be equal to or greater than 5 μm, and X2 may be zero. Further, the dimensions may be different between the depletion region 16 below the first end portion 21a and the depletion region 16 below the second end portion 21b.

A thickness of the depletion region 16 in the y-direction is defined as Y1 and a thickness of the body layer 13 in the y-direction is defined as Y2. A relationship of 0<Y1<Y2 is satisfied.

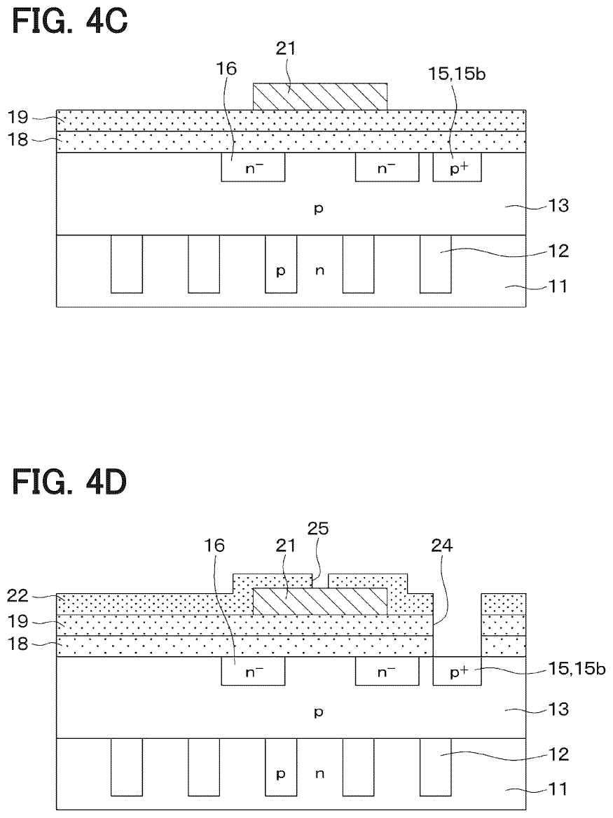

A method for manufacturing the semiconductor device 1 will be described with reference to FIGS. 4A to 4D in which the active region 2 and the substrate 10 are not illustrated. In the step shown in FIG. 4A, an n-type substrate 10 made of SiC is prepared, and a drift layer 11 made of SiC is epitaxially grown on the upper surface of the substrate 10. Then, a p-type column region 12 is formed in the drift layer 11 by ion implantation. Furthermore, a body layer 13 is formed by ion implantation.

In the step shown in FIG. 4B, an n-type region 14, a p+ type region 15, and a depletion region 16 are formed in the body layer 13 by ion implantation. The n-type region 14, the p+ type region 15, and the depletion region 16 may be formed in any order. When forming the depletion region 16, the film formation conditions and ion implantation conditions are set so that a donor density N_{D}, which will be described later, satisfies Formula 4. As a result, the depletion region 16 becomes depleted when the applied voltage between the drain electrode 28 and the source electrode 26 is 0 V. After the n-type region 14, the p+ type region 15, and the depletion region 16 are formed, a trench 17 is formed by etching.

In the step shown in FIG. 4C, a field insulating film 18 is formed by thermal oxidation on the upper surface of the body layer 13, the p+ type region 15b, and the depletion region 16 in the inactive region 3. Then, a gate insulating film 19 is formed by thermal oxidation on the upper surface of the body layer 13 exposed from the field insulating film 18, the upper surface of the n-type region 14, the upper surface of the p+ type region 15a, the wall and bottom surfaces of the trench 17, and the upper surface of the field insulating film 18. Thereafter, a gate electrode 20 is formed inside the trench 17 by chemical vapor deposition (CVD), and a first gate wiring 21 is formed on the upper surface of the gate insulating film 19.

In the step shown in FIG. 4D, an interlayer insulating film 22 is formed by thermal oxidation on the upper surface of the gate insulating film 19, the gate electrode 20, and the first gate wiring 21. Then, the trench 23, 24, 25 is formed by etching. After the step shown in FIG. 4D, a source electrode 26 and a second gate wiring 27 are formed on the upper surface of the substrate 10 by sputtering, and a drain electrode 28 is formed on the lower surface of the substrate 10, thereby forming the semiconductor device 1 shown in FIG. 1.

The conditions under which the depletion region 16 becomes depleted will be explained. In the step shown in FIG. 4B, depletion progresses from the body layer 13 toward the center of an area to be the depletion region 16. A dimension of the depleted region in a direction from the body layer 13 toward the center of the depletion region 16 is defined as W_{depl,n}. When a laterally elongated depletion region 16 is formed, that is, when X1+X2>Y1 is satisfied, the entire depletion region 16 becomes depleted when W_{depl,n}≥Y1 is satisfied. When a vertically elongated depletion region 16 is formed, that is, when X1+X2<Y1, the entire depletion region 16 becomes depleted when W_{depl,n}≥(X1+X2)/2 is satisfied.

The dimension W_{depl,n} is represented by Formula 1, in which ε_{SiC} represents the dielectric constant of SiC, ψ_{bi} represents the built-in potential of the depletion region 16, q represents the elementary electric charge, N_{A} represents the acceptor density of the body layer 13, and No represents the donor density of the depletion region 16.

$${W}_{depl , n} = \sqrt{\frac{2 {ε}_{s i c} {ψ}_{b i}}{q} \frac{{N}_{A}}{{N}_{D} ( {N}_{A} + {N}_{D} )}} \qquad Formula 1$$

When N_{D}<<N_{A} is satisfied, Formula 1 can be transformed into Formula 2.

$${W}_{depl , n} = \sqrt{\frac{2 {ε}_{s i c} {ψ}_{b i}}{q} \frac{1}{{N}_{D}}} \qquad Formula 2$$

From Formula 2, the donor density N_{D} is given as shown in Formula 3.

$${N}_{D} = \frac{2 {ε}_{s i c} {ψ}_{b i}}{q} \frac{1}{{W}_{d e p l , n}^{2}} \qquad Formula 3$$

Therefore, if the dimension W_{depl,n} required for the entire depletion region 16 to be depleted is denoted as W_{depl,n1}, the range of the donor density No is shown in Formula 4.

$${N}_{A} > {N}_{D} > \frac{2 {ε}_{s i c} {ψ}_{b i}}{q} \frac{1}{{W}_{d e p l , n 1}^{2}} \qquad Formula 4$$

The operation of the semiconductor device 1 will be described. In the semiconductor device 1, when a gate voltage equal to or greater than the threshold voltage is applied to the gate electrode 20, an inversion layer is formed in the body layer 13 near the trench 17, and a drain-source current flows according to the voltage between the drain electrode 28 and the source electrode 26. When the gate voltage is below the threshold voltage, the inversion layer is not formed and no drain-source current flows.

During the recovery operation, when the semiconductor device 1 is turned off, a displacement current flows into the body layer 13 via the PN junction capacitance between the drift layer 11 and the body layer 13. The displacement current is drawn out to the source electrode 26 via the body layer 13 and the p+ type region 15b. At this time, due to the path resistance of the body layer 13, the potential of the body layer 13 increases, resulting in a potential difference between the first gate wiring 21 and the body layer 13.

Specifically, the potential difference generated between the first gate wiring 21 and the body layer 13 is defined as ΔV. The current flowing through the body layer 13 is defined as I. The path resistance of the body layer 13 is defined as Rs. Then ΔV=I×Rs is satisfied. The displacement current is defined as Id and the recovery current is defined as Irr. Then I=Id+Irr is satisfied. When Irr=0 is satisfied, I=Id. The PN junction capacitance between the drift layer 11 and the body layer 13 is defined as C, and the time derivative of the voltage between the drain electrode 28 and the source electrode 26 is defined as dV/dt. Then Id=C×(dV/dt) is satisfied.

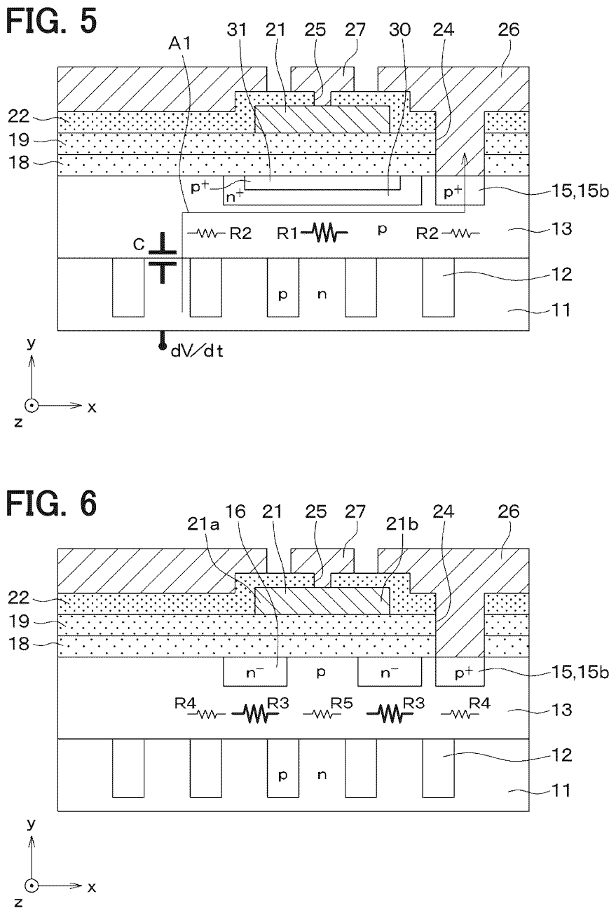

When the potential difference ΔV increases, a high electric field is applied to the field insulating film 18 and the gate insulating film 19, making breakdown more likely to occur. To suppress this, for example as shown in FIG. 5, it is conceivable to form the n+ type region 30 in the surface layer of the body layer 13 beneath the first gate wiring 21, and to form the p+ type region 31 in the surface layer of the n+ type region 30. The p+ type region 31 is separated from the body layer 13 by the n+ type region 30. With such a configuration, it is possible to suppress the displacement current from entering the p+ type region 31, thereby restricting a high electric field from being applied to the field insulating film 18 and the gate insulating film 19.

However, beneath the n+ type region 30 and the p+ type region 31, the body layer 13 becomes thinner compared to other areas. In the current path indicated by the arrow A1, the resistance R1 of the body layer 13 beneath the gate wiring 21 becomes greater than the resistance R2 of the body layer 13 in other areas. Therefore, as shown in FIG. 5, if the n+ type region 30 and the p+ type region 31 are formed over the entire area of the surface layer of the body layer 13 beneath the first gate wiring 21, the region with high path resistance becomes larger, which may lead to device destruction due to heat generation.

In the present embodiment, the depletion region 16 is formed beneath the end portion of the first gate wiring 21. Since the depletion region 16 becomes depleted when the voltage applied between the drain electrode 28 and the source electrode 26 is 0 V, it is less susceptible to the influence of the potential rise in the body layer 13. As a result, in the vicinity of the depletion region 16, the electric field applied to the field insulating film 18 and the gate insulating film 19 is reduced.

In the vicinity of the end portion of the first gate wiring 21, a higher electric field is likely to be applied to the field insulating film 18 and the gate insulating film 19 compared to the area inward of the end portion of the first gate wiring 21, making breakdown more likely to occur. Therefore, by forming the depletion region 16 beneath the end portion of the first gate wiring 21, breakdown of the field insulating film 18 and the gate insulating film 19 can be efficiently suppressed.

The depletion region 16 is not formed beneath the area inward of the end portion of the first gate wiring 21, and the upper surface of the body layer 13 is exposed from the depletion region 16 and is in contact with the field insulating film 18. That is, the body layer 13 located inward of the end portion of the region Re1 has the same thickness as the body layer 13 in the area separated from the region Re1 and the depletion region 16 in the x-direction.

The resistance R3 of the body layer 13 beneath the depletion region 16 shown in FIG. 6 is greater than the resistance R4 of the body layer 13 in the region located outside the first gate wiring 21 in the x-direction. However, in the present embodiment, the depletion region 16 is formed beneath the end portion of the first gate wiring 21, and is not formed beneath the area inward of the end portion of the first gate wiring 21. As a result, in this area, the resistance R5 of the body layer 13 becomes as low as the resistance R4. Therefore, it is possible to suppress an increase in path resistance and restrict device destruction due to temperature rise.

As described above, in the present embodiment, the depletion region 16 is formed beneath the first gate wiring 21, which becomes depleted when the voltage applied between the drain electrode 28 and the source electrode 26 is 0 V. The depletion region 16 is formed beneath at least a part of the end portion of the first gate wiring 21, and the upper surface of the body layer 13 is exposed from the depletion region 16 under at least a part of the inward area of the end portion of the first gate wiring 21. As a result, it is possible to suppress the breakdown of the field insulating film 18 and the gate insulating film 19 due to applied electric fields, as well as to suppress device destruction caused by temperature rise, thereby improving the recovery breakdown tolerance of the semiconductor device 1.

In the configuration shown in FIG. 5, since the side and bottom surfaces of the p+ type region 31 need to be covered by the n+ type region 30, dimensional constraints in the x, y, and z directions become more stringent, which may reduce the degree of freedom in layout. In contrast, in the present embodiment, since the depletion region 16 is of n− type, there are fewer dimensional constraints compared to the case where a stacked structure of the n+ type region 30 and the p+ type region 31 is used, resulting in a higher degree of freedom in layout.

### Second Embodiment

A second embodiment will be described below. This embodiment differs from the first embodiment in the arrangement of the depletion region 16, while the other aspects are the same as those of the first embodiment. Therefore, only the differences from the first embodiment will be described.

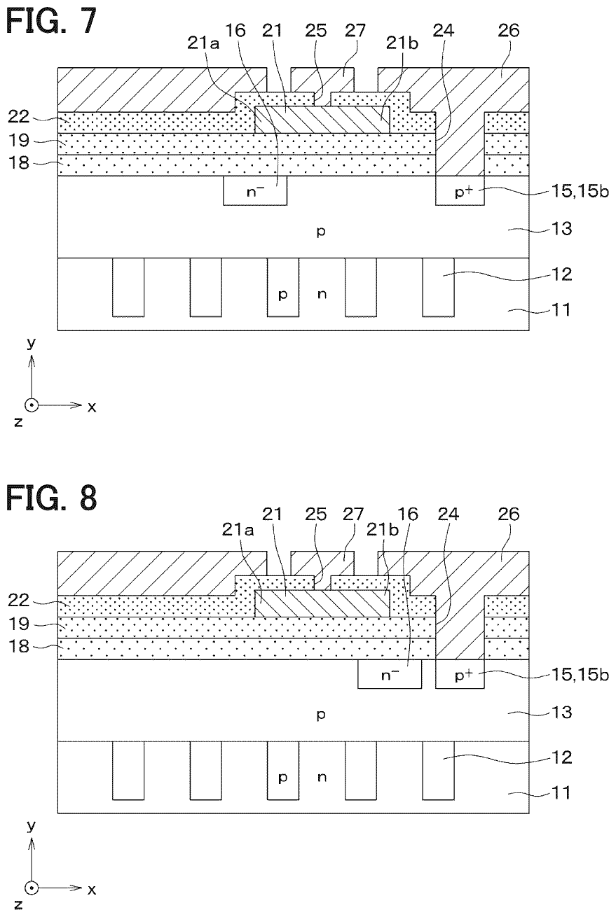

As shown in FIG. 7, the depletion region 16 is not formed beneath the second end portion 21b, but is formed only beneath the first end portion 21a. In the body layer 13, the potential tends to rise more easily in regions farther from the p+ type region 15b, which is in contact with the source electrode 26. Therefore, beneath the first end portion 21a, which is farther from the p+ type region 15b, high electric fields are likely to be applied to the field insulating film 18 and the gate insulating film 19. In contrast, by forming the depletion region 16 only beneath the first end portion 21a, it is possible to efficiently suppress breakdown of the field insulating film 18 and the gate insulating film 19, while also reducing the path resistance beneath the second end portion 21b to further suppress device destruction due to temperature rise.

This embodiment can achieve the same effects as the first embodiment by having the same configuration and operation as the first embodiment.

According to the present embodiment, the following effects can be obtained.

The depletion region 16 is formed only beneath the first end portion 21a. Accordingly, it is possible to suppress breakdown of the field insulating film 18 and the gate insulating film 19, while also reducing the path resistance beneath the second end portion 21b to further suppress device destruction due to temperature rise.

### Third Embodiment

A third embodiment will be described. This embodiment differs from the first embodiment in the arrangement of the depletion region 16, while the other aspects are the same as those of the first embodiment. Therefore, only the differences from the first embodiment will be described.

As shown in FIG. 8, the depletion region 16 is not formed beneath the first end portion 21a, but is formed only beneath the second end portion 21b. Depending on the layout of each part of the semiconductor device 1, displacement current may concentrate, making the field insulating film 18 and the gate insulating film 19 beneath the second end portion 21b, which is close to the p+ type region 15b in contact with the source electrode 26, more susceptible to breakdown. In such cases, by forming the depletion region 16 only beneath the second end portion 21b, it is possible to suppress breakdown of the field insulating film 18 and the gate insulating film 19, while also reducing the path resistance beneath the first end portion 21a and thereby further suppressing device failure due to temperature rise.

This embodiment can achieve the same effects as the first embodiment based on the same configuration and operation as the first embodiment.

According to the present embodiment, the following effects can be obtained.

The depletion region 16 is formed only beneath the second end portion 21b. Accordingly, it is possible to further suppress device failure due to temperature rise by reducing the path resistance beneath the first end portion 21a, while suppressing breakdown of the field insulating film 18 and the gate insulating film 19.

### Fourth Embodiment

A fourth embodiment will be described. This embodiment differs from the first embodiment in that the shape of the depletion region 16, and is otherwise the same as the first embodiment. Therefore, only the differences from the first embodiment will be described.

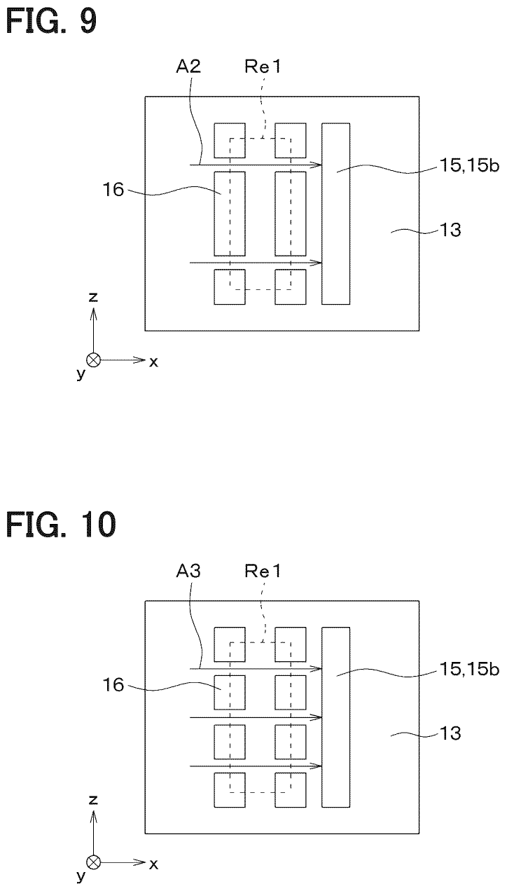

In this embodiment, the depletion regions 16 formed along the first end portion 21a and the second end portion 21b are each divided into plural segments. Specifically, as shown in FIG. 9, the depletion region 16 is separated into corner portions formed at corners of the region Re1 and linear portions extending in the z-direction along the side of the region Re1.

In the current path indicated by the arrow A2, the body layer 13 is thicker and the path resistance of the body layer 13 is lower compared to the path passing beneath the depletion region 16, so device destruction due to temperature rise can be further suppressed.

In FIG. 9, the depletion region 16 is divided into the corner portions and the linear portions. The linear portion may be further divided into plural segments. For example, as shown in FIG. 10, the linear portion of the depletion region 16 is divided into two segments at its central part. In the configuration shown in FIG. 10, in the current path indicated by the arrow A3, the path resistance of the body layer 13 is lower compared to the path passing beneath the depletion region 16, so device destruction due to temperature rise can be further suppressed.

Beneath the corner of the first gate wiring 21, destruction of the field insulating film 18 and the gate insulating film 19 due to a rise in the potential of the body layer 13 is more likely to occur compared to other areas. Therefore, the depletion region 16 may be formed only at the corner of the region Re1. In this case, the upper surface of the body layer 13 may be exposed from the depletion region 16 and brought into contact with the field insulating film 18, at the linear portion at the end of the region Re1. Accordingly, device destruction due to temperature rise can be further suppressed.

The position and width of the gap between the segments of the depletion region 16 may be adjusted, when designing the semiconductor device 1, in consideration of the magnitude of the electric field applied to the field insulating film 18 and the gate insulating film 19, as well as the amount of temperature rise in the body layer 13.

This embodiment can achieve the same effects as the first embodiment through the same configuration and operation as the first embodiment.

According to the present embodiment, the following effects can be obtained.

The depletion region 16 is divided into plural sections, along the end of the first gate wiring 21. As a result, destruction of the device due to temperature rise can be further suppressed.

### OTHER EMBODIMENTS

It should be noted that the present disclosure is not limited to the embodiments described above, and various modifications may be made as appropriate. Furthermore, the above embodiments are not mutually exclusive, and may be appropriately combined with each other unless such combination is clearly impossible. It goes without saying that, in the above embodiments, the elements constituting the embodiments are not necessarily essential, except in cases where they are expressly stated to be essential or are considered to be clearly essential in principle. Furthermore, in the above embodiments, when the number, value, quantity, range, or other numerical aspects of the components constituting the embodiments are mentioned, they are not limited to those specific numbers, except in cases where such limitation is expressly stated to be essential or is clearly restricted to a specific number in principle. Furthermore, in the above embodiments, when reference is made to the shape, positional relationship, or the like of components, such shape or positional relationship is not limited to those specifically mentioned, except in cases where a particular shape or positional relationship is expressly specified or is clearly limited to a specific one in principle.

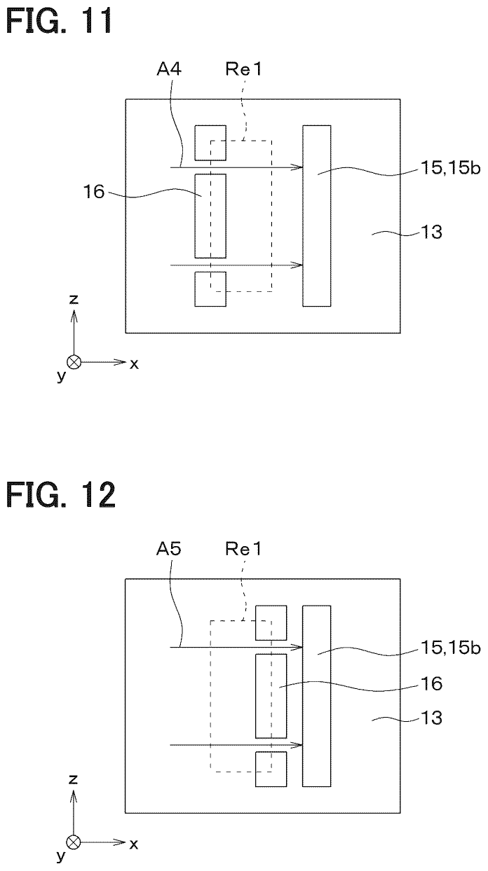

For example, as shown in FIG. 11, the fourth embodiment may be combined with the second embodiment. In the configuration shown in FIG. 11, the path resistance of the body layer 13 in the current path indicated by the arrow A4 is reduced, thereby further suppressing temperature rise as compared to the second embodiment. Further, as shown in FIG. 12, the fourth embodiment may be combined with the third embodiment. In the configuration shown in FIG. 12, the path resistance of the body layer 13 in the current path indicated by the arrow A5 is reduced, thereby further suppressing temperature rise as compared to the third embodiment.

The depletion region 16 may be formed under a part of the inner portion of the first gate wiring 21 located inward of the end portion. The depletion region 16 may be formed under the entire end portion of the first gate wiring 21. In addition to being formed under the first end portion 21a and the second end portion 21b, the depletion region 16 may also be formed in a rectangular frame shape along the lower sides of both ends of the first gate wiring 21 in the z-direction. Further, the depletion region 16 may not be fully depleted. For example, there may be a non-depleted region at the center of the depletion region 16.

In the embodiments, the semiconductor device 1 has a MOSFET element, but the semiconductor device 1 may have a JFET (Junction Field Effect Transistor) element or an IGBT (Insulated Gate Bipolar Transistor) element. Further, the drift layer 11 may not have an SJ (Super Junction) structure formed therein.

In the embodiments, the n-type is used as the first conductivity type and the p-type is used as the second conductivity type; however, the present disclosure may also be applied to a p-channel element in which the p-type is the first conductivity type and the n-type is the second conductivity type.

What is claimed is:

1. A semiconductor device comprising:
a drift layer of a first conductivity type;
a body layer of a second conductivity type arranged on an upper surface of the drift layer;
a lower electrode disposed on a lower surface of the drift layer;
a gate wiring disposed on an upper surface of the body layer and connected to a gate electrode;
a gate insulating film disposed between the upper surface of the body layer and the gate wiring;
an upper electrode disposed on the upper surface of the body layer; and
a depletion region of the first conductivity type to be depleted in a state where a voltage of 0 V is applied between the lower electrode and the upper electrode, wherein
the depletion region is arranged in an upper surface layer of the body layer and located below the gate wiring,
the depletion region is positioned under at least a part of an end portion of the gate wiring, and
an upper surface of the body layer is exposed from the depletion region at location inward of the end portion of the gate wiring.

2. The semiconductor device according to claim 1, wherein
a dimension of the depletion region protruding outward from the end portion of the gate wiring in a surface direction parallel to the upper surface of the body layer is defined as X1, and a relationship of 0<X1<5 μm is satisfied.

3. The semiconductor device according to claim 1, wherein
a dimension of the depletion region overlapping with the gate wiring in a surface direction parallel to the upper surface of the body layer is defined as X2,
a dimension of the gate wiring in the surface direction is defined as X3, and
a relationship of 0<X2<X3 is satisfied.

4. The semiconductor device according to claim 1, wherein
a thickness of the depletion region is defined as Y1,
a thickness of the body layer is defined as Y2, and
a relationship of 0<Y1<Y2 is satisfied.

5. The semiconductor device according to claim 1, wherein
a formula of
$${N}_{A} > {N}_{D} > \frac{2 {ε}_{s i c} {ψ}_{b i}}{q} \frac{1}{{W}_{d e p l , n 1}^{2}}$$
is satisfied, in which
N_{A} represents an acceptor density of the body layer,
N_{D} represents a donor density of the depletion region,
ε_{SiC} represents a dielectric constant of SiC,
ψ_{bi} represents a built-in potential of the depletion region,
q represents an elementary electric charge,
W_{depl,n} represents a dimension of a depleted region in a direction from the body layer toward a center of the depletion region, and
W_{depl,n1} represents a dimension W_{depl,n} required for an entirety of the depletion region to be depleted.

6. The semiconductor device according to claim 1, wherein
the upper electrode within a trench that penetrates the gate insulating film is in contact with a contact portion formed in the upper surface layer of the body layer,
the gate wiring has a first end portion and a second end portion in a surface direction parallel to the upper surface of the body layer,
the first end portion is located opposite to the contact portion with respect to a center of the gate wiring,
the second end portion is located adjacent to the contact portion with respect to the center of the gate wiring, and
the depletion region is formed only below the first end portion.

7. The semiconductor device according to claim 1, wherein
the upper electrode within a trench that penetrates the gate insulating film is in contact with a contact portion formed in the upper surface layer of the body layer,
the gate wiring has a first end portion and a second end portion in a surface direction parallel to the upper surface of the body layer,
the first end portion is located opposite to the contact portion with respect to a center of the gate wiring,
the second end portion is located adjacent to the contact portion with respect to the center of the gate wiring, and
the depletion region is formed only below the second end portion.

8. The semiconductor device according to claim 1, wherein the depletion region is divided into a plurality of regions along an end portion of the gate wiring.

9. The semiconductor device according to claim 1, wherein the first conductivity type is n-type, and the second conductivity type is p-type.

10. The semiconductor device according to claim 1, wherein the first conductivity type is p-type, and the second conductivity type is n-type.
